(19) United States
(12) Patent Application Publication
(10) Pub. No.: US 2026/0305447 A1
(43) Pub. Date: Oct. 1, 2026

(54) TEMPORARY PROTECTION FILM FOR SEMICONDUCTOR DEVICE MANUFACTURING AND METHOD FOR MANUFACTURING SEMICONDUCTOR DEVICE

(71) Applicant: Resonac Corporation, Minato-ku, Tokyo (JP)

(72) Inventors: Shinnosuke TAKEGASA, Tokyo (JP); Kodai ITO, Tokyo (JP)

(21) Appl. No.: 19/477,095

(22) PCT Filed: Aug. 6, 2024
(86) PCT No.: PCT/JP2024/028136

§ 371 Date: Oct. 20, 2025

(30) Foreign Application Priority Data
Aug. 23, 2023 (JP) 2023-135761

(51) Int. Cl. H10W 74/01; B32B 7/06; B32B 7/12; H10P 72/70; H10W 42/00

(52) U.S. Cl. CPC H10W 74/019; B32B 7/06; B32B 7/12; H10P 72/74; H10W 42/00; B32B 2307/7376; B32B 2457/14

(57) ABSTRACT

A temporary protective film for producing a semiconductor device, comprising a support film and an adhesive layer provided on the support film, wherein the adhesive layer comprises a polymer containing alkyl (meth)acrylate and (meth)acryloylmorpholine as monomer units, and does not contain a cross-linking agent.

### TECHNICAL FIELD

The present disclosure relates to a temporary protective film for semiconductor device manufacturing and a method for producing a semiconductor device.

### BACKGROUND ART

In semiconductor packages, a structure is sometimes adopted in which an encapsulating layer is formed only on the semiconductor element side of the lead frame, and the back surface of the lead frame is exposed. In the production of a semiconductor package having this structure, there is a risk that the encapsulant may spread to the back surface of the lead frame when the encapsulating layer is formed. In order to prevent this, a method is known in which a temporary protective film is attached to the back surface of the lead frame (Patent Literature 1). The temporary protective film is peeled off from the lead frame after the encapsulating layer is formed.

### CITATION LIST

### Patent Literature

Patent Literature 1: International Publication No. WO 2001/035460

### SUMMARY OF INVENTION

### Technical Problem

For a temporary protective film, it is desirable to have an adhesive force that allows it to be attached to an adherend such as a lead frame at room temperature (25° C.), and yet be easily peeled off from the adherend after encapsulation. Therefore, an object of one aspect of the present invention is to provide a temporary protective film that can be easily peeled off after encapsulation without impairing the adhesive force after attachment at room temperature.

### Solution to Problem

According to studies by the present inventors, when using a polymer comprising alkyl (meth)acrylate and (meth)acryloylmorpholine as monomer units in the adhesive layer of a temporary protective film, it is conventionally common to use a cross-linking agent in combination. However, it has been found that by not using a cross-linking agent in combination, the film can be easily peeled off after encapsulation without impairing the adhesive force of the temporary protective film after attachment at room temperature.

The present invention includes the following aspects.
[1] A temporary protective film for production of a semiconductor device, comprising a support film and an adhesive layer provided on the support film, wherein the adhesive layer contains a polymer containing alkyl (meth)acrylate and (meth)acryloylmorpholine as monomer units, and does not contain a cross-linking agent.
[2] The temporary protective film according to [1], wherein the polymer further contains a monomer having an acidic group as a monomer unit.
[3] The temporary protective film according to [1] or [2], wherein a thickness of the adhesive layer is 3 μm or less, and a storage modulus of the temporary protective film at 200° C. is 5 MPa or more.
[4] A method for producing a semiconductor device, including: attaching a temporary protective film to one surface side of a substrate; mounting a semiconductor element on a surface of the substrate opposite to the temporary protective film; encapsulating the semiconductor element; and peeling the temporary protective film from the substrate, in this order, wherein the temporary protective film comprises a support film and an adhesive layer provided on the support film, and the adhesive layer contains a polymer containing alkyl (meth)acrylate and (meth)acryloylmorpholine as monomer units, and does not contain a cross-linking agent.
[5] The method according to [4], wherein the polymer further contains a monomer having an acidic group as a monomer unit.
[6] The method according to [4] or [5], wherein a thickness of the adhesive layer is 3 μm or less, and a storage modulus of the temporary protective film at 200° C. is 5 MPa or more.

### Advantageous Effects of Invention

According to one aspect of the present invention, it is possible to provide a temporary protective film that can be easily peeled off after encapsulation without impairing the adhesive force after attachment at room temperature.

### BRIEF DESCRIPTION OF DRAWINGS

FIG. 1 is a cross-sectional view showing an embodiment of a temporary protective film.

FIG. 2 is a cross-sectional view for illustrating an embodiment of a method for manufacturing a semiconductor device.

FIG. 3 is a cross-sectional view for illustrating an embodiment of a method for manufacturing a semiconductor device.

FIG. 4 is a cross-sectional view showing an embodiment of a semiconductor device.

FIG. 5 is a perspective view illustrating an embodiment of a reel body.

### DESCRIPTION OF EMBODIMENTS

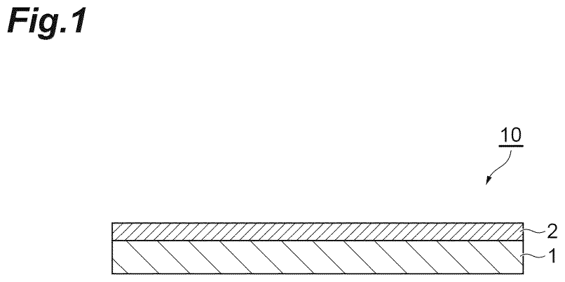

Hereinafter, embodiments of the present invention will be described. FIG. 1 is a cross-sectional view showing a temporary protective film according to an embodiment. As shown in FIG. 1, a temporary protective film 10 according to an embodiment comprises a support film 1 and an adhesive layer 2 provided on the support film 1. The temporary protective film 10 can be used as a temporary protective film for semiconductor device manufacturing. More specifically, the temporary protective film 10 can be used as a temporary protective film for semiconductor encapsulation molding to temporarily protect a lead frame during encapsulation molding by being attached to the back surface (the surface opposite to the surface on which a semiconductor element is mounted) of the lead frame in the step of encapsulation molding for forming an encapsulating layer that encapsulates the semiconductor element mounted on a die pad of the lead frame.

The support film 1 may be a film of at least one polymer selected from the group consisting of polyimide, polyamide, polyamide-imide, polysulfone, polyethersulfone, polyphenylene sulfide, polyetherketone, polyarylate, polyetheretherketone, and polyethylene naphthalate, and may preferably be a film of polyimide. The polyimide may be an aromatic polyimide. The support film 1 may be a film of copper, aluminum, stainless steel, or nickel. When the support film 1 is a polymer film, its surface may be surface-treated by methods such as chemical treatment like alkali treatment and silane coupling treatment, physical treatment like sand mat treatment, plasma treatment, and corona treatment.

The thickness of the support film 1 may be, for example, 5 μm or more, 10 μm or more, 15 μm or more, or 20 μm or more, and may be 100 μm or less, 50 μm or less, or 30 μm or less. The ratio T₂/T₁ of the thickness T₂ of the adhesive layer 2 to the thickness T₁ of the support film 1 may be 0.05 or more, 0.08 or more, or 0.1 or more, and may be 0.5 or less, 0.3 or less, or 0.2 or less.

The adhesive layer 2 comprises a polymer containing alkyl (meth)acrylate and (meth)acryloylmorpholine as monomer units (hereinafter also referred to as “acrylic polymer”).

The alkyl group in the alkyl (meth)acrylate (the alkyl group portion other than the (meth)acryloyl group) may be linear or branched. The number of carbon atoms in the alkyl group may be 2 or more, or 3 or more, and may be 30 or less, 20 or less, 10 or less, 7 or less, 5 or less, or 4 or less, and may be 2 or 4.

Examples of the alkyl (meth)acrylate include methyl (meth)acrylate, ethyl (meth)acrylate, propyl (meth)acrylate, butyl (meth)acrylate, pentyl (meth)acrylate, n-hexyl (meth)acrylate, n-heptyl (meth)acrylate, n-octyl (meth)acrylate, 2-ethylhexyl (meth)acrylate, nonyl (meth)acrylate, and decyl (meth)acrylate.

The content of the alkyl (meth)acrylate, based on the total amount of monomer units in the acrylic polymer, may be 70% by mass or more, 75% by mass or more, or 80% by mass or more, and may be 92% by mass or less, 90% by mass or less, or 88% by mass or less.

The content of (meth)acryloylmorpholine, based on the total amount of monomer units in the acrylic polymer, may be 7% by mass or more, 7.5% by mass or more, 8% by mass or more, 8.5% by mass or more, or 9.0% by mass or more, and may be 20% by mass or less, 18% by mass or less, 17% by mass or less, 16.5% by mass or less, or 16% by mass or less.

The mass ratio of the content of (meth)acryloylmorpholine to the content of alkyl (meth)acrylate ((meth)acryloylmorpholine/alkyl (meth)acrylate) may be 0.08/1 or more, 0.09/1 or more, or 0.1/1 or more, and may be 0.3/1 or less, 0.25/1 or less, 0.23/1 or less, 0.21/1 or less, or 0.2/1 or less.

The acrylic polymer may further contain other monomers as monomer units in addition to alkyl (meth)acrylate and (meth)acryloylmorpholine. The other monomers have a polymerizable group copolymerizable with alkyl (meth)acrylate and (meth)acryloylmorpholine. The polymerizable group may be, for example, an ethylenically unsaturated group.

The other monomer may be a monomer having an acidic group in addition to the polymerizable group. The acidic group may be, for example, a carboxyl group or a sulfo group, and is preferably a carboxyl group. Examples of the cross-linkable monomer having a carboxyl group include (meth)acrylic acid, carboxyethyl (meth)acrylate, carboxypentyl (meth)acrylate, monohydroxyethyl acrylate phthalate, and 2-acryloyloxyethyl succinate.

The other monomer may be a monomer having a hydroxyl group in addition to the polymerizable group. Examples of this monomer include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate; and hydroxyalkylcycloalkane (meth)acrylates such as (4-hydroxymethylcyclohexyl) methyl (meth)acrylate.

The content of the other monomers, based on the total amount of monomer units in the acrylic polymer, may be 0.1% by mass or more, 0.5% by mass or more, or 1% by mass or more, and may be 5% by mass or less, 4% by mass or less, or 3% by mass or less.

The weight-average molecular weight (Mw) of the acrylic polymer may be 550,000 or more, or 600,000 or more, and from the viewpoint of easier peeling of the temporary protective film after encapsulation, is preferably 650,000 or more, more preferably 750,000 or more, still more preferably 850,000 or more, and particularly preferably 950,000 or more. The Mw of the acrylic polymer may be 2,000,000 or less, 1,800,000 or less, 1,600,000 or less, 1,400,000 or less, 1,200,000 or less, or 1,100,000 or less.

The molecular weight distribution (Mw/Mn) of the acrylic polymer may be 2.0 or less, 1.9 or less, 1.8 or less, or 1.7 or less, and may be 1.0 or more, 1.2 or more, 1.4 or more, or 1.6 or more.

The Mw and Mw/Mn of the acrylic polymer are measured by the following procedure.

They were determined by gel permeation chromatography (GPC) using a high-performance liquid chromatograph (manufactured by Tosoh Corporation, model HLC-8320GPC). Two TSKgel Super Multipore HZ-H columns (manufactured by Tosoh Corporation) are used, with a tetrahydrofuran solution as the mobile phase and a differential refractometer as the detector. The measurement conditions are a column temperature of 40° C., a sample concentration of 10 mg/mL, a sample injection volume of 10 μm, and a flow rate of 0.2 mL/min. A calibration curve is prepared using polystyrene as a standard substance (molecular weights: 1,090,000, 775,000, 427,000, 289,000, 190,000, 96,400, 37,900, 10,200, 2,630, 440), and the weight-average molecular weight (Mw) and number-average molecular weight (Mn) are measured. The molecular weight distribution (Mw/Mn) is calculated from these measured values.

The acid value of the acrylic polymer may be 10 mgKOH/g or more, or 20 mgKOH/g or more, and may be 40 mgKOH/g or less, or 30 mgKOH/g or less. The hydroxyl value of the acrylic polymer may be 1 mgKOH/g or more, or 2 mgKOH/g or more, and may be 10 mgKOH/g or less, or 5 mgKOH/g or less. The acid value and hydroxyl value of the acrylic polymer are measured in accordance with the method described in JIS K0070.

The content of the acrylic polymer, based on the total amount of the adhesive layer 2, may be 80% by mass or more, 85% by mass or more, or 90% by mass or more, and may be 99.5% by mass or less, or 99% by mass or less.

The adhesive layer 2 does not contain a cross-linking agent. Because the adhesive layer 2 does not contain a cross-linking agent, the temporary protective film can be easily peeled off after encapsulation without impairing the adhesive force after attachment at room temperature. Furthermore, in one embodiment, when the adhesive layer 2 does not contain a cross-linking agent, an increase in viscosity of the varnish for forming the adhesive layer 2 can also be suppressed.

The adhesive layer 2 may further contain other components other than the acrylic polymer. Examples of other components include polymers other than the acrylic polymer and coupling agents.

The thickness of the adhesive layer 2 may be 1 μm or more, or 2 μm or more, and may be 20 μm or less, 15 μm or less, 10 μm or less, 5 μm or less, 4 μm or less, or 3 μm or less.

The storage modulus of the temporary protective film 10 at 200° C. may be 0.5 MPa or more, or 1 MPa or more, and may preferably be 2 MPa or more, 3 MPa or more, 4 MPa or more, or 5 MPa or more, and for example, 10 MPa or less. The storage modulus of the temporary protective film at 200° C. is measured by the method described in the Examples.

The temporary protective film 10 exhibits a high storage modulus even when the adhesive layer 2 is thin. Specifically, in one embodiment, even if the thickness of the adhesive layer 2 is 3 μm or less, the storage modulus of the temporary protective film 10 at 200° C. can be in the above-mentioned range (particularly, preferably 2 MPa or more, 3 MPa or more, 4 MPa or more, or 5 MPa or more). When the temporary protective film 10 exhibits such a high elastic modulus, wire bonding can be performed cleanly.

In another embodiment, the temporary protective film may further comprise a cover film provided on the surface of the adhesive layer opposite to the support film. That is, the temporary protective film may comprise a support film, an adhesive layer, and a cover film in this order. The cover film may be a polyethylene terephthalate film. The thickness of the cover film may be 10 μm or more, and may be 100 μm or less.

In another embodiment, the temporary protective film may further comprise a non-adhesive layer provided on the side of the support film opposite to the adhesive layer. The non-adhesive layer may be a resin layer that has substantially does not exhibit adhesive properties to an adherend at 0 to 270° C. The non-adhesive layer may contain a resin that is a thermoplastic resin, a thermosetting resin (cured product), or a combination thereof. The non-adhesive layer may further contain a filler (e.g., ceramic powder, glass powder, silver powder, copper powder, resin particles, rubber particles), a coupling agent, or the like. The thickness of the non-adhesive layer may be 1 μm or more, and may be 10 μm or less.

The temporary protective film can be manufactured, for example, by a method including a step of forming the adhesive layer by applying a varnish containing an acrylic polymer and a cross-linking agent onto a support film and removing the solvent from the coating film.

Next, a method for manufacturing a semiconductor device using the above-described temporary protective film will be described. The method for manufacturing a semiconductor device of one embodiment comprises, in the following order: a step S1 of attaching a temporary protective film to one surface side of a substrate; a step S2 of mounting a semiconductor element on a surface of the substrate opposite to the temporary protective film; a step S3 of encapsulating the semiconductor element; and a step S4 of peeling the temporary protective film from the substrate. Hereinafter, as an example, a method for manufacturing a semiconductor device (semiconductor device package) where the substrate is a lead frame will be described more specifically.

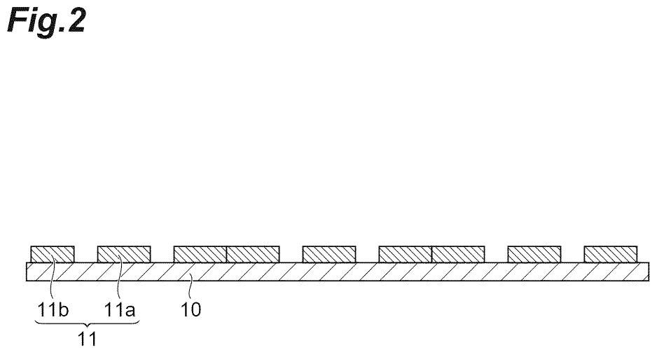

FIG. 2 is a cross-sectional view illustrating an embodiment (step S1) of the method for manufacturing a semiconductor device. In step S1, as shown in FIG. 2, a temporary protective film 10 is attached to the back surface, which is one surface of a lead frame 11 having a die pad 11a and inner leads 11b. The temporary protective film 10 is attached in such a manner that the adhesive layer of the temporary protective film 10 is in contact with the lead frame 11.

The lead frame 11 may be formed from, for example, an iron-based alloy such as Alloy 42, copper, or a copper-based alloy. The lead frame 11 may have a molded body formed from copper or a copper-based alloy, and a coating layer of palladium, gold, silver, or the like covering its surface.

The temporary protective film 10 is excellent in adhesive strength at room temperature (for example, 25° C.), and therefore can be attached to the lead frame 11 at room temperature. The temporary protective film 10 may be attached to the lead frame 11 while performing heating and pressurization. In this case, the heating temperature may be 150° C. or higher, and may be 400° C. or lower. The pressure may be 0.5 MPa or higher, and may be 30 MPa or lower. The time for heating and pressurization may be 1 second or longer, and may be 60 seconds or shorter.

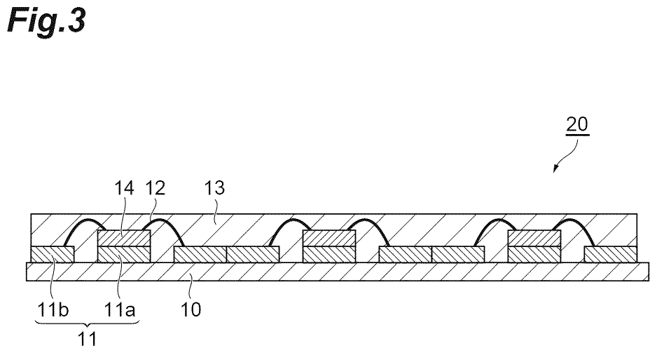

FIG. 3 is a cross-sectional view for explaining an embodiment (step S2 and step S3) of the method for manufacturing a semiconductor device. In step S2, as shown in FIG. 3, a semiconductor element 14 is mounted on the surface of the die pad 11a opposite to the temporary protective film 10. The semiconductor element 14 is adhered to the die pad 11a via an adhesive (e.g., silver paste). After adhering the semiconductor element 14 to the die pad 11a, reflow connection (such as CuClip connection) may be performed under conditions of a maximum temperature of 250 to 440° C., or 250 to 400° C., and for 1 to 30 minutes.

Next, the semiconductor element 14 is connected to the inner leads 11b using a wire 12. The wire 12 may be, for example, a gold wire, a copper wire, or a palladium-coated copper wire. The wire 12 may be bonded to the semiconductor element 14 and the inner lead 11b using ultrasonic waves and pushing pressure while performing heating at, for example, 200 to 350° C.

Subsequently, in step S3, as shown in FIG. 3, an encapsulating layer 13 that encapsulates the semiconductor element 14 and the wire 12 is formed. Thus, a temporarily protected encapsulation molding product 20 having the lead frame 11, the semiconductor element 14, and the encapsulating layer 13 is obtained.

The encapsulating layer 13 is formed by encapsulation molding using an encapsulant. By encapsulation molding, an encapsulation molding product 20 having a plurality of semiconductor elements 14 and an encapsulating layer 13 that encapsulates them collectively can be obtained. During the encapsulation molding, the provision of the temporary protective film 10 suppresses the encapsulant from wrapping around to the back surface side of the lead frame 11.

The temperature during the formation of the encapsulating layer 13 (temperature of the encapsulant) may be 140 to 200° C., or 160 to 180° C. The pressure during the formation of the encapsulating layer may be 6 to 15 MPa, or 7 to 10 MPa. The time for encapsulation molding may be 1 to 5 minutes, or 2 to 3 minutes.

The encapsulant may contain, for example, an epoxy resin such as a cresol novolac epoxy resin, a phenol novolac epoxy resin, a biphenyl diepoxy resin, or a naphthol novolac epoxy resin. The encapsulant may also contain a filler, a flame retardant such as a bromine compound, a wax component, and the like.

After the formation of the encapsulating layer 13 (encapsulation molding), the temporary protective film 10 is peeled off from the lead frame 11 and the encapsulating layer 13 of the obtained encapsulation molding product 20. When curing the encapsulating layer 13, the temporary protective film 10 may be peeled off either before or after the curing of the encapsulating layer 13.

The temperature at which the temporary protective film 10 is peeled is not particularly limited, but may be room temperature (e.g., 5 to 35° C.), or may be equal to or higher than the glass transition temperature (Tg) of the adhesive layer. In this case, the temporary protective film 10 is peeled off from the lead frame 11 and the encapsulant even more preferably. If the Tg of the acrylic polymer in the adhesive layer is, for example, 5° C. or lower, or 0° C. or lower, the Tg of the adhesive layer becomes equal to or lower than room temperature, and the temporary protective film is likely to be peeled off well at room temperature.

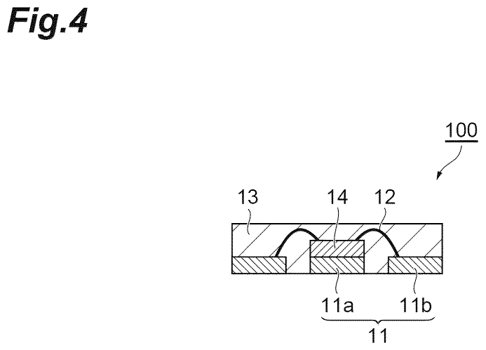

When the lead frame 11 includes a plurality of patterns having die pads 11a and inner leads 11b, the encapsulation molding product 20 can be divided as necessary to obtain a plurality of semiconductor devices (semiconductor packages) 100 of FIG. 4, each having one semiconductor element. That is, when the lead frame 11 has a plurality of die pads 11a and a semiconductor element 14 is mounted on each of the plurality of die pads 11a, the manufacturing method according to one embodiment may further comprise obtaining a semiconductor device (semiconductor package) 100 having one die pad 11a and one semiconductor element 14 by dividing the encapsulation molding product 20 after peeling the temporary protective film 10 from the encapsulation molding product 20.

The temporary protective film may be in a long strip form and used in the state of a reel body wound around a core. In this case, the temporary protective film is unwound from the reel body and attached to the adherend.

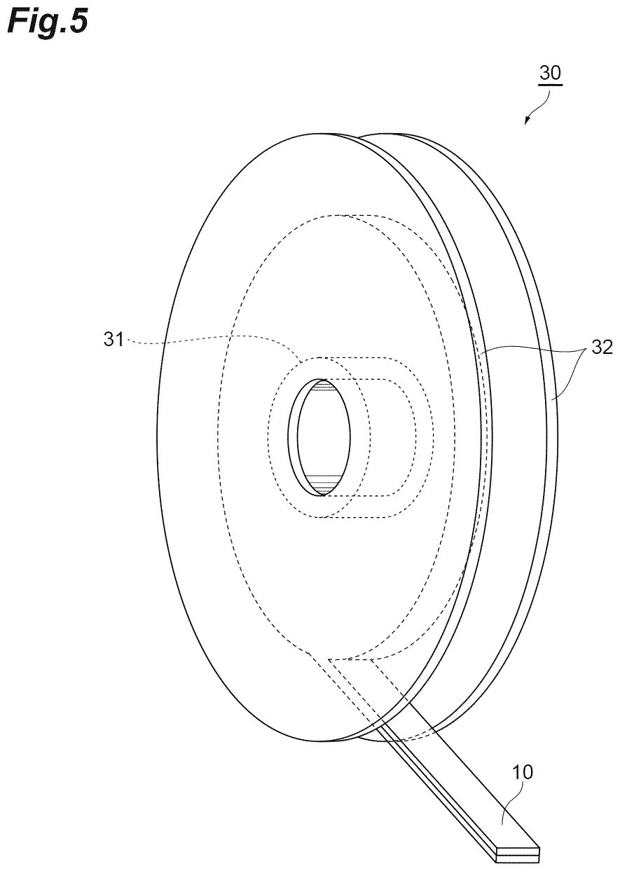

FIG. 5 is a perspective view showing an embodiment of a reel body. As shown in FIG. 5, a reel body 30 according to an embodiment comprises a core 31, a temporary protective film 10 wound on the core 31, and side plates 32. The width (length in the direction orthogonal to the winding direction) of the core 31 and the temporary protective film 10 may be 1 mm or more, 5 mm or more, or 10 mm or more, and may be 1000 mm or less, 800 mm or less, or 500 mm or less. In another embodiment, the reel body may not comprise side plates.

### EXAMPLES

Hereinafter, the present invention will be described more specifically with reference to Examples. However, the present invention is not limited to the Examples.

### Example 1

An acrylic polymer A-1 (weight-average molecular weight (Mw): 600,000, molecular weight distribution (Mw/Mn): 1.7) containing, as monomer units, 80% by mass of butyl acrylate, 16% by mass of acryloylmorpholine, 3% by mass of acrylic acid, and 1% by mass of other monomers (monomers having a hydroxyl group) was dissolved in cyclohexanone to obtain a varnish for forming an adhesive layer. A polyimide film (thickness: 25 μm, manufactured by Toray-DuPont Co., Ltd., trade name: Kapton 100EN) was prepared as a support film. The obtained varnish was applied onto one surface of the support film. The coating film on the support film was dried by heating at 90° C. for 1.5 minutes and at 260° C. for 1.5 minutes to form an adhesive layer with a thickness of 2 μm. A temporary protective film was thus obtained.

### Examples 2-3

Temporary protective films were obtained in the same manner as in Example 1, except that the thickness of the adhesive layer was changed as shown in Table 1.

### Comparative Example 1

A temporary protective film was obtained in the same manner as in Example 1, except that a varnish was prepared by adding 7 parts by mass of a cross-linking agent represented by the following formula:

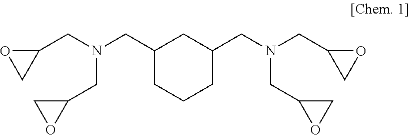 [SMILES: C1CC(CN(CC2CO2)CC2CO2)CC(CN(CC2CO2)CC2CO2)C1]

to 100 parts by mass of the acrylic polymer A-1, and the thickness of the adhesive layer was changed as shown in Table 1.

### Example 4

A temporary protective film was obtained in the same manner as in Example 2, except that an acrylic polymer A-2 (weight-average molecular weight (Mw): 1,000,000, molecular weight distribution (Mw/Mn): 1.9) containing, as monomer units, 90.5% by mass of butyl acrylate, 5.5% by mass of acryloylmorpholine, 3% by mass of acrylic acid, and 1% by mass of other monomers (monomers having a hydroxyl group) was used instead of the acrylic polymer A-1.

### Example 5

A temporary protective film was obtained in the same manner as in Example 4, except that the thickness of the adhesive layer was changed as shown in Table 1.

### (Evaluation of Varnish Viscosity Increase)

The increase in viscosity was evaluated for the varnish for forming the adhesive layer used in producing each temporary protective film. Specifically, using 1.1 mL of the varnish, the viscosity at 25° C. of the varnish on the day of preparation and one month after the preparation date was measured using a viscometer L-type (manufactured by). The increase in viscosity of the varnish was evaluated based on the following criteria.
A: The rate of increase in the viscosity of the varnish one month after the preparation date, relative to the viscosity of the varnish on the day of preparation, is less than 30%.
B: The said rate of increase is 30% or more, or the varnish one month after the preparation date gelled and lost its fluidity.

### (Measurement of Storage Modulus of Temporary Protective Film)

Test pieces were prepared by cutting each temporary protective film into a size of 5 mm×8 mm. After heating the test piece at 180° C. for 1 hour, followed by heating at 200° C. for 1 hour, the storage modulus of the test piece at 200° C. was measured using a dynamic viscoelasticity measuring device (UBM Co., Ltd., Rheogel-E4000). The test piece was fixed using a jig for shear modulus with a tightening torque of 7 cN·m. The measurement conditions were: measurement mode: frequency dependence, measurement frequency: 20 Hz to 600 Hz, load: constant control.

(Measurement of Adhesive Strength after Room Temperature Attachment)

A CDA194 palladium-plated plate (PPF, manufactured by Shinko Electric Industries Co., Ltd.) was prepared as a lead frame. Each temporary protective film, cut into a size of 10 mm×50 mm, was attached to this lead frame with the adhesive layer facing the lead frame, using a hand roller under conditions of 25° C. and a load of 20 N. Then, using a force gauge, each temporary protective film was peeled off at 25° C. in a direction of 90 degrees to the main surface of the lead frame at a speed of 50 mm/min. The maximum value of the load per 10 mm width of the adhesive layer (N/m) at that time was measured as the adhesive strength after room temperature attachment (90-degree peel strength). The results are shown in Table 1. If the adhesive strength after room temperature attachment is 20 N/m or more, it can be said that the said adhesive strength is not impaired.

(Measurement of Peel Strength after Encapsulation)

Using a molding machine (manufactured by APIC YAMADA CORPORATION), an encapsulating layer was formed with an encapsulant (trade name: GE-300, manufactured by Resonac Corporation) on the surface of the lead frame opposite to the temporary protective film, to which the temporary protective film was attached in the same manner as in the “Measurement of Adhesive Strength after Room Temperature Attachment” above. The encapsulation conditions were 175° C., 6.8 MPa, for 2 minutes. Thereafter, at 25° C., each temporary protective film was peeled off in a direction of 180 degrees to the main surface of the lead frame at a speed of 50 mm/min, and the peel strength at that time was measured with a force gauge. At this time, the peel strength from the portion where the adhesion area between the temporary protective film and the lead frame was large was taken as the peel strength on a lead frame, and the peel strength from the portion where the adhesion area between the temporary protective film and the encapsulating layer was large was taken as the peel strength on an encapsulating layer. A smaller peel strength after encapsulation means that the temporary protective film can be easily peeled off after encapsulation.

TABLE 1

| | | | | | Comparative | | |
|---|---|---|---|---|---|---|---|
| | | Example 1 | Example 2 | Example 3 | Example 1 | Example 4 | Example 5 |
| Type of acrylic polymer | | A-1 | A-1 | A-1 | A-1 | A-2 | A-2 |
| Cross-linking agent | | None | None | None | Present | None | None |
| Varnish thickening | | A | A | A | B | A | A |
| Thickness of adhesive layer (μm) | | 2 | 3 | 4 | 5 | 3 | 4 |
| Storage modulus (MPa) | | ≥5 | ≥5 | ≥1 | ≥1 | ≥5 | ≥1 |
| Adhesive strength after attachment | | 23 | 32 | 40 | 25 | 25 | 35 |
| at room temperature (N/m) | | | | | | | |
| Peel strength | On lead frame | 102 | 90 | 76 | 175 | 70 | 50 |
| after encapsulation | On encapsulating | 200 | 188 | 176 | 250 | 165 | 135 |
| (N/m) | layer | | | | | | |

### REFERENCE SIGNS LIST

1 . . . support film, 2 . . . adhesive layer, 10 . . . temporary protective film, 11 . . . lead frame, 11a . . . die pad, 11b . . . inner lead, 12 . . . wire, 13 . . . encapsulating layer, 14 . . . semiconductor element, 20 . . . encapsulation molding product, 100 . . . semiconductor device.

1. A temporary protective film for production of semiconductor device, comprising:
a support film; and
an adhesive layer provided on the support film,
wherein the adhesive layer comprises a polymer comprising alkyl (meth)acrylate and (meth)acryloylmorpholine as monomer units, and does not contain a cross-linking agent.

2. The temporary protective film according to claim 1, wherein the polymer further comprises a monomer having an acidic group as a monomer unit.

3. The temporary protective film according to claim 1, wherein a thickness of the adhesive layer is 3 μm or less, and a storage modulus of the temporary protective film at 200° C. is 5 MPa or more.

4. A method for producing a semiconductor device comprising:
attaching a temporary protective film to one surface side of a substrate;
mounting a semiconductor element on a surface of the substrate opposite to the temporary protective film;
encapsulating the semiconductor element; and
peeling the temporary protective film from the substrate,
wherein the temporary protective film comprises:
a support film; and
an adhesive layer provided on the support film, and
wherein the adhesive layer contains a polymer comprising alkyl (meth)acrylate and (meth)acryloylmorpholine as monomer units, and does not contain a cross-linking agent.

5. The method according to claim 4, wherein the polymer further comprises a monomer having an acidic group as a monomer unit.

6. The method according to claim 4, wherein a thickness of the adhesive layer is 3 μm or less, and a storage modulus of the temporary protective film at 200° C. is 5 MPa or more.
